(19) United States
(12) Patent Application Publication
(10) Pub. No.: US 2006/0166379 A1
(43) Pub. Date: Jul. 27, 2006

(54) Method for manufacturing ferroelectric capacitor

(76) Inventor: Motoki Kobayashi, Kanagawa (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/335,582

(22) Filed: Jan. 20, 2006

(30) Foreign Application Priority Data
Jan. 25, 2005 (JP) 017450/2005

(51) Int. Cl. H01L 21/00

(52) U.S. Cl. 438/3

(57) ABSTRACT

A method for manufacturing a ferroelectric capacitor having a lower electrode, a ferroelectric film, and an upper electrode stacked on one another comprises the steps of performing batch dry-etching thereto, processing and forming the upper electrode, the ferroelectric film, and lower electrode, performing a process for removing reactive products adhered to sidewall portions of the ferroelectric capacitor, cleaning the ferroelectric capacitor with concentrated sulfuric acid, and performing a process for passivating sidewall portions of the ferroelectric film.

### FIELD OF THE INVENTION

The present invention relates to a method for manufacturing a semiconductor device containing a ferroelectric capacitor, and particularly to a method for etching a ferroelectric capacitor section.

### BACKGROUND OF THE INVENTION

A ferroelectric capacitor is generally processed by dry etching for the purpose of its miniaturization in the process of manufacturing the ferroelectric capacitor. However, a problem arises in that with the execution of the dry etching, etching damage occurs in a ferroelectric film and hence a leak current occurs in the capacitor. There is a need to remove etching damaged layers to realize a high-performance ferroelectric capacitor free of the leak current. There has been known, for example, a method for removing damaged layers by wet etching (refer to Japanese Patent Laid-Open No. 2004-260177).

Upon dry-etching the ferroelectric capacitor, reactive products yielded by etching adhere to capacitor sidewall portions and lead to the occurrence of the leak current. Therefore, the reactive products are removed by wet etching or the like (refer to Japanese Patent Laid-Open No. 8(1996)-296067 and Japanese Patent Laid-Open No. 2000-173999).

However, in a method for dry-etching a ferroelectric capacitor having an upper electrode, a ferroelectric film, and a lower electrode stacked on one another, particularly, in its forming method for performing batch etching, reductive chlorine (Cl₂) is generally used as gas upon dry etching a lower electrode composed of platinum (Pt). Therefore, damaged layers are easy to be formed in the ferroelectric film and reactive products such as chlorides are also susceptible to adhere.

Each of the damaged layers is formed so as to intrude from the exposed side surface of the ferroelectric film to the inside, and the dielectric polarization characteristic of the ferroelectric film is degraded. As a result, the leak current flows from the upper electrode to the lower electrode. Although the reactive products can be removed in a wet-etching process subsequent to the dry etching, the perfect removal of the damaged layers is difficult and there has been the fear of promotion to the damaged layers.

### SUMMARY OF THE INVENTION

The present invention aims to batch dry-etch, using a mask film, a ferroelectric capacitor having a lower electrode, a ferroelectric film, and an upper electrode laminated on one another, perform a process for removing reactive products adhered to sidewall portions of the ferroelectric capacitor and thereafter carry out a process for passivating sidewall portions of the ferroelectric film to thereby recover damage at dry etching.

In a manufacturing method of the present invention, a capacitor having a laminated structure is batch dry-etched and thereafter concentrated sulfuric acid capable of passivating a metal material is used as a cleaning solution. It is thus possible to prevent deterioration of residual polarization of a ferroelectric film and effectively remove damaged layers formed in the ferroelectric film upon dry etching. As a result, a leak current at a capacitor section is suppressed. According to the present invention as well, a ferroelectric capacitor which realizes improvements in both etching form free of sidewall residuals and capacitor characteristic, and is excellent in reliability, can be fabricated with satisfactory yield and at low cost.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a process sectional view for describing a method for manufacturing a semiconductor device, according to an embodiment of the present invention;

FIG. 2 is a process sectional view following FIG. 1, for describing the semiconductor device manufacturing method according to the embodiment of the present invention;

FIG. 3 is a ferroelectric capacitor sectional view for explaining the relationship between the area of a ferroelectric capacitor and the area of a damaged layer;

FIG. 4 is a hysteresis curve for describing the relationship between the area of a ferroelectric capacitor and a polarization amount; and

FIG. 5 is a result showing the characteristics of a ferroelectric capacitor which has been experimented using test patterns.

### DETAILED DESCRIPTION OF THE PREFERRED EMBODIMENTS

The present invention will hereinafter be described in detail with reference to the accompanying drawings.

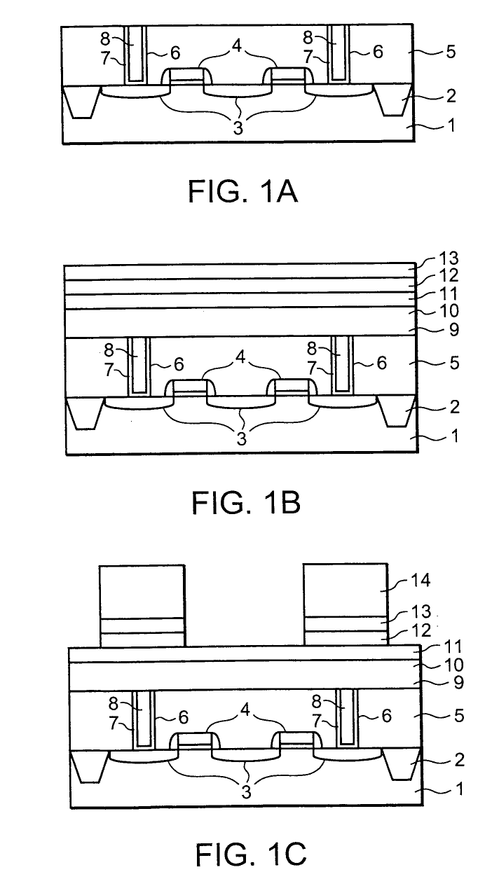

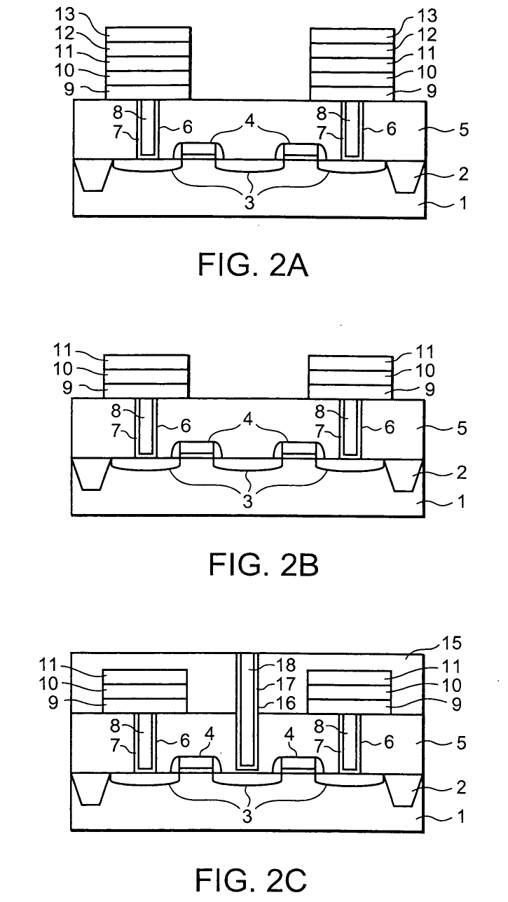

A method for manufacturing a semiconductor device containing a ferroelectric capacitor, according to a preferred embodiment of the present invention will be described with reference to FIGS. 1A through 1C and FIGS. 2A and 2B. FIGS. 1A through 1C and FIG. 2A and 2B are respectively sectional views showing manufacturing processes of the semiconductor device.

In a manner similar to the related art, device isolation insulating films 2 and source-drain diffusion layers 3 are formed in a semiconductor substrate 1 made up of silicon (Si). Further, gate insulting films and gate electrodes are formed on the semiconductor substrate 1 to form MOS transistors 4. Thereafter, an insulating film 5 is formed over the semiconductor substrate 1 to cover the MOS transistors 4 and then planarized. Openings 6 are defined in the insulting film 5 to expose the diffusion layers 3. Barrier films 7 made up of titanium nitride (TiN) and plug electrodes 8 made up of tungsten (W) are respectively embedded into the openings 6 (see FIG. 1A).

Next, a TiAlN film is formed 50 nm thick as an antioxidant film for each plug electrode 8 by using a sputtering method. An Ir film of 400 nm and an IrO₂ film of 100 nm are respectively sequentially formed as adhesive layers in continuous form by the sputtering method. Further, a Pt film of 50 nm is formed by the sputtering method. A laminated film of the TiAlN film, Ir film and IrO₂ film constitutes a lower electrode 9.

Sequentially, an SBT (tantalic acid strontium bismuth: SrBi₂Ta₂O₉) film is formed as a ferroelectric film 10 by a sol-gel method. In the present embodiment, a method for forming the SBT film will be explained as three-layer coating. Described specifically, a precursor solution with SBT dissolved therein is spun on the lower electrode 9 as a first time, followed by being crystal-annealed at 700° C. Then, the precursor solution is spun on the lower electrode 9 as a second time, followed by being crystal-annealed at 700° C. Further, the precursor solution is spun on the lower electrode 9 as a third time, followed by being crystal-annealed at 800° C. The thickness of the ferroelectric film 10 is formed as 100 nm, for example. Further, a Pt film is formed as an upper electrode 11 by the sputtering method. Thus, a laminated structure is obtained which is constituted of the lower electrode 9, the ferroelectric film 10 and the upper electrode 11 (see FIG. 1B).

Thereafter, a first mask film 12 corresponding to a TiN film used as a hard mask is formed 10 nm by the sputtering method. Similarly, a P-TEOS (plasma tetraethoxysilane) oxide film is formed 100 nm on the first mask film 12 as a second mask film 13 by a plasma CVD method.

Next, a resist film 14 is formed on the second mask film 13. Capacitor patterns are transferred onto the resist 14 by using the normal lithography method, and the second mask film 13 and the first mask film 12 are processed or worked with the resist 14 as a mask (see FIG. 1C). A C₄F₈/Ar/O₂ mixed gas is used for etching of the second mask film 13, and a BCl₃/Cl₂ mixed gas is used for etching of the first mask film 12. And the resist is removed using the normal oxygen (O₂) plasma ashing and sulphuric acid cleaning. Although the sulphuric acid cleaning is used in the present embodiment, an organic remover may be used.

Next, the upper electrode 11, the ferroelectric film 10 and the lower electrode 9 are collectively etched. The Pt film for the upper electrode 11 is etched with the second mask film 13 as a mask. The etching makes use of a parallel plate RIE apparatus and is performed under the condition that a mixed gas of Cl₂/O₂=5/15 sccm or Cl₂/O₂/Ar=5/15/10 sccm is used, and gas pressure, RF power at a frequency of 13.56 MHz, and RF power at 450 MHz are set as 2 mTorr, 1000 W, and 100 W respectively. Incidentally, a Cl₂/Ar mixed gas may be used as etching gas.

In order to etch Pt as fast as possible, a wafer temperature may preferably be raised to approximately 350 to 450° C. at which Pt chlorides evaporate spontaneously during Cl₂ plasma. Raising the wafer temperature enables suppression of re-adhesion of reactive products such as the Pt chlorides or the like to sidewalls of the ferroelectric film 10.

Further, the ferroelectric SBT film is etched. This is done under the condition that a wafer temperature is set to 25 to 350° C., a mixed gas Cl₂/Ar=10/10 sccm is used, gas pressure is set as 1 mTorr, RF power at 13.56 MHz is set as 550 W, and RF power at 450 KHz is set as 120 W. As etching gas, a Cl₂ gas, a Cl₂/O₂ mixed gas, or a Cl₂/O₂/Ar mixed gas may be used.

After etching of the ferroelectric film 10, the Pt film, IrO₂ film, Ir film and TiAlN film of the lower electrode 9 are etched (see FIG. 2A). This is done under the condition that a wafer temperature ranges from 350° C. to 450° C., a mixed gas of Cl₂/O₂=5/15 sccm or a mixed gas of Cl₂/O₂/Ar=5/15/10 sccm is used, gas pressure is set to 1 or 2 mTorr, RF power at 13.56 MHz is set to 1000 W, and RF power at 450KHz is set to 100 W. As etching gas, a Cl₂/Ar mixed gas may be used. A ferroelectric capacitor section is formed by etching of the lower electrode.

After completion of etching up to the lower electrode, ashing is done within the same apparatus. Ashing is performed with a mixed gas of N₂/O₂=180/1320 sccm and at a wafer temperature of 175° C. Reactive products adhered to the surface of the substrate are removed by ashing. Since a substrate to be processed is taken out from another apparatus where ashing is done by such an apparatus, reactive products composed of an electrode material, a ferroelectric and etching gas might react with moisture in the atmosphere to produce foreign substances. It is desirable to take out the processed substrate after the processing up to ashing within the same apparatus.

The reactive products hard to remove by ashing are eliminated by cleaning. Concentrated sulfuric acid of 89% is used for cleaning. After the processing using the concentrated sulfuric acid, pure-water cleaning is done. The adhered reactive products are constituted of Pt, Ir corresponding to the electrode materials, and ferroelectric strontium St, bismuth Bi, tantalum Ta, etc. Since the concentrated sulfuric acid of 89% passivates a metal, it does not dissolve the electrode materials and the ferroelectric. Since, however, the sulfuric acid is brought to diluted sulphuric acid upon subsequent pure-water cleaning although within an extreme short period of time, it can dissolve metal reactive products inappreciably.

Subsequently, the second mask film 13 and the first mask film 12 are removed to form a capacitor section (see FIG. 2B). Further, a CVD oxide film of an insulating film 15 is formed using a CVD method, and the insulating film 15 is planarized using etchback, a CMP method and the like (see FIG. 2C). Thereafter, although not shown in the figure, contact holes are made open, and wirings connected to the MOS transistor and the ferroelectric capacitor, etc. are formed, thereby leading to completion of a semiconductor device having the ferroelectric capacitor.

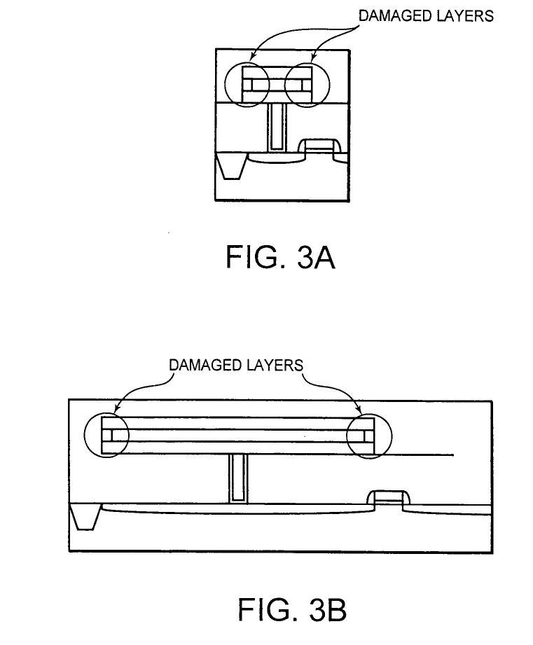

The characteristic of the ferroelectric capacitor will now be explained. In the process of etching the laminated film constituted of the upper electrode 11, ferroelectric film 10 and lower electrode 9, a reduction reaction due to chlorine gas or the like in a dry etching atmosphere occurs when the ferroelectric film 10 is exposed. An SBT oxide used as the ferroelectric film 10 weakens dielectric polarization corresponding to the characteristic of the ferroelectric due to the reduction reaction. Each portion weak in such dielectric polarization corresponds to a damaged layer. The damaged layers are formed at peripheral portions of ferroelectric films so as to intrude from the side surfaces of the ferroelectric films exposed to atmospheres at etching to their interiors as shown in FIGS. 3A and 3B respectively.

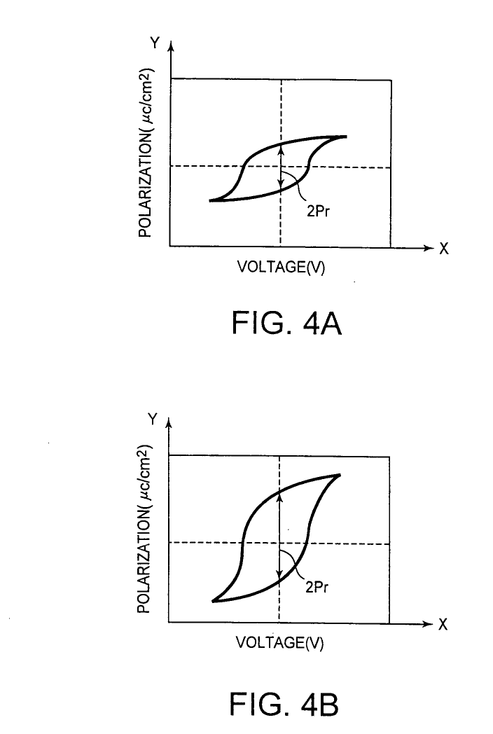

Even though the ferroelectric capacitor is small in area (see FIG. 3A) and large in area (see FIG. 3B), the damaged layers are formed in sizes nearly equal to each other. Therefore, as the ferroelectric capacitor shrinks for the purpose of high integration, the rate of the damaged layer to the effective area of the ferroelectric capacitor relatively increases, and the degree of an influence of damage becomes large. As apparent from hysteresis curves shown in FIGS. 4A and 4B, the residual polarization amount becomes lower as compared with the case where the ferroelectric capacitor is large in area, when the ferroelectric capacitor is small in area.

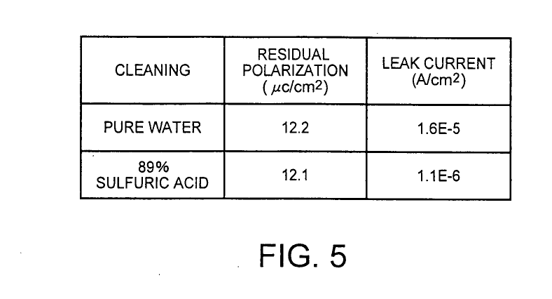

In order to confirm the effects of the present embodiment, an SBT ferroelectric capacitor having 1.4 μm² was used as each test pattern and batch dry-etched, followed by being subjected to cleaning processing by 89% concentrated sulfuric acid and pure water. FIG. 5 shows residual polarization amounts of a post-cleaning SBT film at the present experiment. Even though the SBT film is cleaned with the concentrated sulfuric acid or cleaned with only the pure water without being cleaned with the concentrated sulfuric acid, this does not influence the residual polarization amount subsequent to its cleaning. This result shows that ones dissolved by cleaning using the concentrated sulfuric acid are reactive products alone and the formation of the damaged layer of the ferroelectric, which causes a decrease in the residual polarization amount, is not promoted.

As shown in FIG. 5 as well, capacitor leak currents were measured where the concentrated sulfuric acid and pure water were used after dry-etching. It is understood that when the SBT film is cleaned with the concentrated sulfuric acid, the capacitor leak current is reduced about one digit as compared with the case in which the SBT film is cleaned with the pure water alone, and the capacitor leak current reaches a level equivalent to the leak current characteristic of the SBT film itself unsubjected to dry etching. This shows that the damaged layer of the SBT film, which leads to the leak current under the use of the concentrated sulfuric acid, has been removed. It is considered that since Sr, Bi, and Ta are reduced and degraded due to the etching gas and changed from oxides to metal form in the case of the SBT film, the damaged layer increases in electrical conductivity and hence the leak current increases. It is considered that according to the present experiment, the leak current has decreased because the metals in the SBT film are passivated by the concentrated sulfuric acid.

According to the present invention, when the capacitors each having the laminated structure are batch-etched, the use of the concentrated sulfuric acid capable of passivating the metal material in the post-dry etching cleaning makes it possible to suppress an increase in the residual polarization amount and decrease the capacitor leak current. The reactive products formed on the pattern sidewalls upon batch etching of the capacitors each having the laminated structure are constituted of Pt and Ir corresponding to the electrode materials and the ferroelectric St, bismuth Bi, tantalum Ta, etc. The concentrated sulfuric acid of greater than a density at which passivation is allowed, does not dissolve the electrode materials and the ferroelectric. Since, however, the concentrated sulfuric acid results in diluted sulfuric acid upon subsequent pure-water cleaning although within an extreme short period of time, it brings about the effect of being capable of dissolving the metal reactive products inappreciably.

Although the present embodiment has explained the SBT film as the ferroelectric film by way of example, the present invention can be applied even to a case in which a metal-oxide ferroelectric film such as PZT (PbTiO₃-PbZrO₃: lead zirconate titanate) or the like is used. Although the present embodiment has explained the case where the SBT film is used as the ferroelectric film, and the sol-gel method is used as the method for forming the SBT film, the present invention can be applied even to an SBT film to be formed by another forming method such as a CVD method.

Further, the lower electrode 9 having the laminated structure constituted of the TiAlN film used as the antioxidant film of each plug electrode 8, the Ir film/IrO₂ film used as the adhesive layer, and the Pt film used as the main electrode film is configured in the present embodiment. However, the antioxidant film of the plug electrode 8 is not limited to the TiAlN film. The present invention can be applied even to a case in which another antioxidant film is used. The present invention can be applied even to a case in which the upper electrode 11 and the lower electrode 9 are shaped in either island or stripe form.

In the manufacturing method of the present invention, a ferroelectric capacitor which realizes improvements in both etching form free of sidewall residuals and capacitor characteristic, and is excellent in reliability, can be manufactured with satisfactory yield and at low cost.

While the preferred form of the present invention has been described, it is to be understood that modifications will be apparent to those skilled in the art without departing from the spirit of the invention. The scope of the invention is to be determined solely by the following claims.

What is claimed is:

1. A method for manufacturing a ferroelectric capacitor having a lower electrode, a ferroelectric film, and an upper electrode laminated on one another, comprising the steps of:
performing batch dry-etching using a mask film to form the upper electrode, ferroelectric film, and lower electrode;
removing reactive products adhered to sidewall portions of the ferroelectric capacitor; and
performing a process for passivating sidewalls of the ferroelectric film.

2. The method according to claim 1, wherein the ferroelectric film contains a metal oxide compound.

3. The method according to claim 2, wherein the ferroelectric film is an SBT film.

4. The method according to claim 2, wherein the passivation is performed by concentrated sulfuric acid.

5. The method according to claim 4, wherein the density of the concentrated sulfuric acid is 89%.

6. The method according to claim 4, wherein a process for removing the reactive products is ashing.

7. The method according to claim 4, wherein the mask film is a hard mask.

8. The method according to claim 7, wherein the mask film is a laminated film.

9. A method for manufacturing a ferroelectric capacitor constituted of a lower electrode, a ferroelectric film, and an upper electrode, comprising the steps of:
forming the upper electrode, the ferroelectric film, and the lower electrode by a dry etching method;
performing a process for removing reactive products adhered to sidewall portions of the ferroelectric capacitor; and
performing a process for passivating sidewall portions of the ferroelectric film.

10. The method according to claim 9, wherein the ferroelectric film contains a metal oxide compound.

11. The method according to claim 10, wherein the ferroelectric film is an SBT film.

12. The method according to claim 10, wherein the passivation is performed by concentrated sulfuric acid.

13. The method according to claim 12, wherein the density of the concentrated sulfuric acid is 89%.

14. The method according to claim 12, wherein the process for removing the reactive products is ashing.

15. The method according to claim 12, wherein the mask film is a hard mask.

16. The method according to claim 15, wherein the mask film is a laminated film.
